(19) United States
(12) Patent Application Publication
(10) Pub. No.: US 2011/0027535 A1
(43) Pub. Date: Feb. 3, 2011

(54) ANISOTROPIC PARTICLE-ARRANGED STRUCTURE AND METHOD OF MANUFACTURING THE SAME

(75) Inventors: Chul Jong HAN, Seoul (KR); Yong Hoon KIM, Gyeonggi-do (KR); Min Suk OH, Seoul (KR); Soon Hyung KWON, Seoul (KR)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: KOREA ELECTRONICS TECHNOLOGY INSTITUTE, Gyeonggi-do (KR)

(21) Appl. No.: 12/846,309

(22) Filed: Jul. 29, 2010

(30) Foreign Application Priority Data
Jul. 31, 2009 (KR) 10-2009-0070326

(51) Int. Cl. B32B 3/10; B05D 1/04; H05K 3/00

(52) U.S. Cl. 428/172; 427/458; 216/13

(57) ABSTRACT

Provided are a light, thin, short and small, and multi-functional anisotropic particle-arranged structure including two electrodes having fine pitches that are repeatedly compressed to be connected to external elements, and a method of manufacturing the anisotropic particle-arranged structure. The anisotropic particle-arranged structure includes an elastic polymer layer, and elastic conductors or elastic thermal conductors formed in the elastic polymer layer so that upper and lower portions of the elastic conductors or elastic thermal conductors are exposed.

### BACKGROUND OF THE INVENTION

1. Field of the Invention

The present invention relates to an anisotropic particle-arranged structure and a method of manufacturing the same, and more particularly, to a light, thin, short and small, and multi-functional anisotropic particle-arranged structure including two electrodes having fine pitches that are repeatedly compressed to be connected to external elements, and a method of manufacturing the anisotropic particle-arranged structure.

2. Description of the Related Art

Recently, along with the rapid developments for miniaturization of circuit boards including electronic components such as semiconductor elements mounted thereon, highly-functionalized and highly-integrated circuit boards have been gradually required. As a result, the size of a connecting terminal for connection with a circuit is gradually reduced, and thus there is a need to continually develop a connection technology.

In particular, in order to repeatedly connect and disconnect elements to each other for repair or repetitive use, there is no alternative but a connector. However, due to the great size and connection pitch limitations (about 0.35 mm) of a typical connector, there is a limit in using the typical connector in electronic devices that are gradually changed to be light, thin, short and small.

An anisotropic conductive film (ACF) and a connector have a similar function. The connector provides electrical connection by using mechanical spring-coupling, and the ACF provides electrical connection by using a chemical adhesive force. Although the connector can be repeatedly compressed, it is difficult to obtain a fine pitch in the connector due to its mechanical characteristics. On the other hand, although a fine pitch can be obtained in the ACF, an element using the ACF is limited since the ACF is processed at a high temperature, and it is difficult to repeatedly use the ACF.

### SUMMARY OF THE INVENTION

Aspects of the present invention provide a light, thin, short and small, and multi-functional anisotropic particle-arranged structure including two electrodes having fine pitches that are repeatedly compressed to be connected to external elements, and a method of manufacturing the anisotropic particle-arranged structure.

According to an aspect of the present invention, there is provided an anisotropic particle-arranged structure including an elastic polymer layer, and elastic conductors or elastic thermal conductors formed in the elastic polymer layer so that upper and lower portions of the elastic conductors or elastic thermal conductors are exposed.

In this case, the elastic conductors may each have a spherical shape. An elastic polymer of the elastic polymer layer may be, for example, silicon.

The elastic conductors may be formed to be a single layer in the elastic polymer layer. The elastic polymer has no adhesive properties. In addition, the elastic polymer has an adhesive force of 0.1 gf/in to 5000 gf/in.

According to another aspect of the present invention, there is provided a method of manufacturing an anisotropic particle-arranged structure, the method including preparing elastic conductors or elastic thermal conductors to be a single layer; and filling an elastic polymer between the elastic conductors or elastic thermal conductors so as to expose upper and lower portions of the elastic conductors or elastic thermal conductors to form an elastic polymer layer.

The preparing of the elastic conductors or the elastic thermal conductors may be performed by using an electrostatic-painting method.

The method may further include, when the elastic conductors or the elastic thermal conductors are formed on a soluble adhesive layer formed on a substrate, and the elastic polymer is formed, removing the substrate and the soluble adhesive layer. The substrate and the soluble adhesive layer may be removed by dissolving the soluble adhesive layer. In this case, the soluble adhesive layer may include photoresist.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of an anisotropic particle-arranged structure according to an embodiment of the present invention: and

FIGS. 2A through 2D are cross-sectional views of a method of manufacturing an anisotropic particle-arranged structure, according to an embodiment of the present invention.

### DETAILED DESCRIPTION OF THE INVENTION

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art.

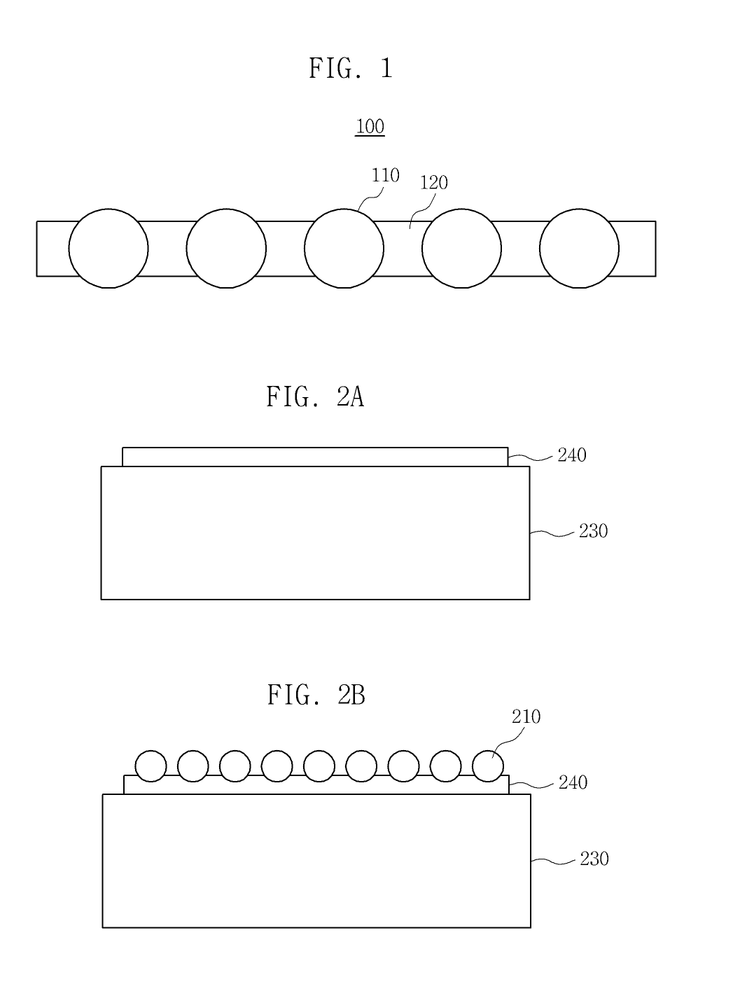

FIG. 1 is a cross-sectional view of an anisotropic particle-arranged structure 100 according to an embodiment of the present invention. The anisotropic particle-arranged structure 100 includes an elastic polymer layer 120; and elastic bodies 110 formed in the elastic polymer layer 120, wherein upper and lower portions of the elastic bodies 110 are exposed, and the elastic bodies 110 are elastic conductors or elastic thermal conductor.

In the anisotropic particle-arranged structure according to the present embodiment, central particle portions formed of an electrical conductive or thermal conductive material, that is, the elastic bodies 110 are connected by an elastic polymer so as to form the elastic polymer layer 120, and upper and lower portions of the elastic bodies 110 are exposed so as to vertically transmit electricity or heat.

The elastic polymer layer 120 may include, for example, silicon. The elastic polymer layer 120 may not have adhesive properties. In addition, the polymer of the elastic polymer layer 120 may have adhesive force of, for example, 0.1 gf/in to 5000 gf/in.

The elastic bodies 110 may be disposed in the elastic polymer layer 120. The elastic bodies 110 may be elastic conductors or elastic thermal conductors. Referring to FIG. 1, the elastic bodies 110 are horizontally arranged in the elastic polymer layer 120. If the elastic bodies 110 of FIG. 1 is an elastic conductor, when opposite electrodes are applied to the upper and lower portions of the anisotropic particle-arranged structure 100 in which the elastic conductors are horizontally arranged, the opposite electrodes may be repeatedly connected and disconnected to the upper and lower portions.

The elastic bodies 110 may each have a spherical shape so as to be smoothly connected to electrodes, and so on. When the elastic bodies 110 each having a spherical shape are formed to be a single layer in the elastic polymer layer 120, the upper and lower portions of the elastic bodies 110 are exposed to complete the manufacture of the anisotropic particle-arranged structure 100. The sizes of the elastic bodies 110 are adjusted so as to control pitches. As the sizes of the elastic bodies 110 are appropriately reduced, a fine pitch connection function may be obtained.

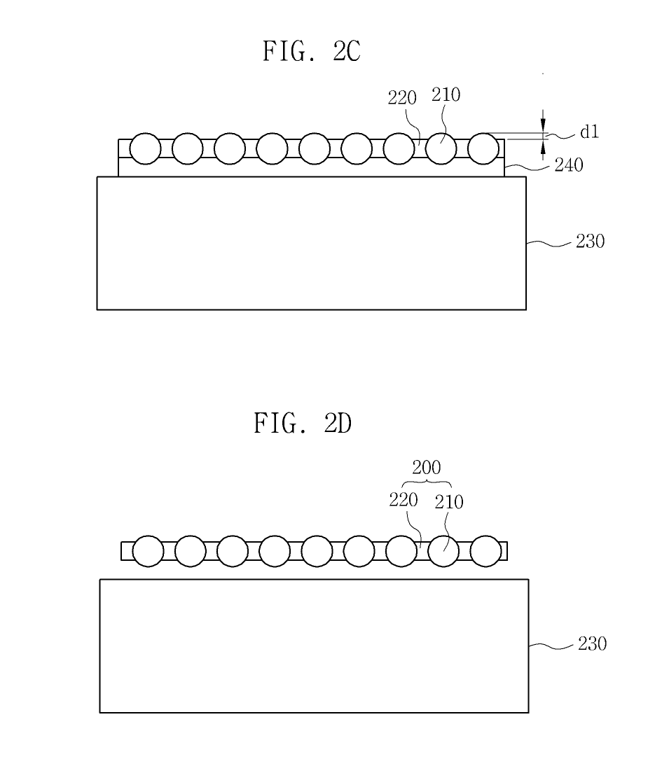

FIGS. 2A through 2D are cross-sectional views of a method of manufacturing an anisotropic particle-arranged structure 200, according to an embodiment of the present invention.

Referring to FIG. 2A, in order to manufacture the anisotropic particle-arranged structure 200, a soluble adhesive agent 240 is coated on a substrate 230 for manufacture. When elastic bodies 210 are formed to be a single layer, the elastic bodies 210 are fixed rather than being moved by using the soluble adhesive agent 240. Thus, the elastic bodies 210 may be uniformly arranged when an elastic polymer layer 220 is formed.

Since the soluble adhesive agent 240 is not required in the anisotropic particle-arranged structure 200, in order to easily remove the soluble adhesive agent 240 later, the soluble adhesive agent 240 may be an adhesive agent having adhesive properties and to be dissolved in a predetermined solvent, such as photoresist. In addition, the thickness of the soluble adhesive agent 240 may be about 10% of the thickness of the elastic body 210. When the soluble adhesive agent 240 is too thick, it may be difficult to dissolve and remove the soluble adhesive agent 240. When the soluble adhesive agent 240 is too thin, particles of the elastic bodies 210 are not appropriately adhered, and thus it may be difficult to fix the elastic bodies 210.

When the soluble adhesive agent 240 is coated on the substrate 230, the elastic bodies 210 that are elastic conductors or elastic thermal conductors are formed to be a single layer on the soluble adhesive agent 240 (FIG. 2B). The elastic bodies 110 are formed to be a single layer by using an electrostatic-painting method. The elastic bodies 210 are restricted to a single layer by a repulsion force between particles of the elastic bodies 210 when a high voltage (about 1.5 kV) is applied to the elastic bodies 110 while applying an air pressure to the elastic bodies 110, and a predetermined distance between the particles is maintained. That is, the particles of the elastic bodies 210 are fixed on the soluble adhesive agent 240 by using an electrostatic-painting method.

Thus, fine pitches of the anisotropic particle-arranged structure 200 may be uniformly formed (FIG. 2D), and thicknesses of the elastic bodies 210 are relatively uniform since the elastic bodies 210 are formed to be a single layer. Thus, circuit boards may be easily connected to both sides of the anisotropic particle-arranged structure 200.

Then, an elastic polymer is filled between the particles of the elastic bodies 210 to form the elastic polymer layer 220 (FIG. 2C). The elastic polymer layer 220 is formed so as to expose upper portions of the elastic bodies 210. When the elastic polymer layer 220 is formed, if the thickness of the elastic polymer layer 220 is greater than the thickness of each particle of the elastic bodies 210, an external electrode portion (not shown) may not be directly connected to upper and lower portions of the anisotropic particle-arranged structure 200 after upper portions of the particles of the elastic bodies 210 are insulated. To address this problem, the thickness of the elastic polymer layer 220 may be smaller than the thickness of the elastic body 210, as shown in FIG. 2C.

Referring to FIG. 2C, a thickness difference between the elastic bodies 210 and the elastic polymer layer 220 is indicated as ‘d1’. The elastic bodies 210 are exposed by the thickness difference ‘d1’. In FIG. 2C, the upper portions of the elastic bodies 210 are partially exposed, but lower portions of the elastic bodies 210 are surrounded by the elastic polymer layer 220 and the soluble adhesive agent 240.

Since anisotropic thermal conduction properties may be obtained when the upper and lower portions of the particles of the elastic bodies 210 are exposed, it is important that the elastic polymer layer 220 does not cover the upper and lower portions of the elastic bodies 210. The upper portions of the elastic bodies 210 may be exposed by adjusting the thickness of the elastic polymer layer 220, but the lower portions of the elastic bodies 210 may be exposed by using another method.

Thus, in order to expose the lower portions of the elastic bodies 210, the soluble adhesive agent 240 that is positioned below the elastic bodies 210 is removed, as shown in FIG. 2D. Simultaneously the substrate 230 for manufacture is removed, and thus the anisotropic particle-arranged structure 200 is separated from the substrate 230.

In Examples 1 and 2, anisotropic particle-arranged structures were manufactured by using methods of manufacturing an anisotropic particle-arranged structure, according to embodiments of the present invention.

### Example 1

A glass substrate having a size of 100 mm×100 mm was prepared as a substrate for manufacture. Photoresist AZ1512 (available from Clariant co.) as a soluble adhesive agent was spin-coated to a thickness of 1 μm on the glass substrate. Electrostatic-painting was performed on an elastic electric conductor (AU 220, and available from Sekisui Chemical) having a diameter of 20 μm to form a single particle layer. The soluble adhesive agent was baked for 10 minutes at a temperature of 80 to be hardened. Then, a silicon adhesive agent having adhesive properties was spin-coated to a thickness of 15 μm, and was hardened for 1 hour at a temperature of 150 When the hardened material was put in acetone to melt the soluble adhesive agent, and the soluble adhesive agent was removed together with the glass substrate, thereby completing the manufacture of an anisotropic particle-arranged structure.

### Example 2

A glass substrate having a size of 100 mm×100 mm was prepared as a substrate for manufacture. Photoresist AZ1512 (available from Clariant co.) as a soluble adhesive agent was spin-coated to a thickness of 2 μm on the glass substrate. Electrostatic-painting was performed on an elastic electric conductor (AU 230, and available from Sekisui Chemical) having a diameter of 30 μm to form a single particle layer. The soluble adhesive agent was baked for 10 minutes at a temperature of 80 to be hardened. Then, a silicon adhesive agent having adhesive properties was spin-coated to a thickness of 25 μm, and was hardened for 1 hour at a temperature of 150 When the hardened material was put in acetone to melt the soluble adhesive agent, and the soluble adhesive agent was removed together with the glass substrate, thereby completing the manufacture of an anisotropic particle-arranged structure.

According to one or more embodiments of the present invention, since two electrodes having fine pitches are repeatedly compressed so as to be connected to external elements, an anisotropic particle-arranged structure is light, thin, short and small, and may be used to inspect a fine electrode pitch, and thus the anisotropic particle-arranged structure may be used in various fields.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. An anisotropic particle-arranged structure comprising:
an elastic polymer layer; and
elastic conductors or elastic thermal conductors formed in the elastic polymer layer so that upper and lower portions of the elastic conductors or elastic thermal conductors are exposed.

2. The anisotropic particle-arranged structure of claim 1, wherein the elastic conductors or elastic thermal conductors each has a spherical shape.

3. The anisotropic particle-arranged structure of claim 1, wherein the elastic conductors or elastic thermal conductors are formed to be a single layer in the elastic polymer layer.

4. The anisotropic particle-arranged structure of claim 1, wherein an elastic polymer of the elastic polymer layer has an adhesive force of 0.1 gf/in to 5000 gf/in.

5. The anisotropic particle-arranged structure of claim 1, wherein the elastic polymer layer has not adhesive properties.

6. The anisotropic particle-arranged structure of claim 1, wherein an elastic polymer of the elastic polymer layer is silicon.

7. A method of manufacturing an anisotropic particle-arranged structure, the method comprising:
preparing elastic conductors or elastic thermal conductors to be a single layer; and
filling an elastic polymer between the elastic conductors or elastic thermal conductors so as to expose upper and lower portions of the elastic conductors or elastic thermal conductors to form an elastic polymer layer.

8. The method of claim 7, wherein the preparing of the elastic conductors or the elastic thermal conductors is performed by using an electrostatic-painting method.

9. The method of claim 7, further comprising: when the elastic conductors or the elastic thermal conductors are formed on a soluble adhesive layer formed on a substrate, and the elastic polymer is formed, removing the substrate and the soluble adhesive layer.

10. The method of claim 9, wherein the removing of the substrate and the soluble adhesive layer is performed by dissolving the soluble adhesive layer.

11. The method of claim 9, wherein the soluble adhesive layer comprises photoresist.
